(19) United States
(12) Patent Application Publication
(10) Pub. No.: US 2009/0095908 A1
(43) Pub. Date: Apr. 16, 2009

(54) APPARATUS AND METHODS FOR CONVERTING AMBIENT HEAT TO ELECTRICITY

(75) Inventor: Rolf Wilhelm Bollhorst, Charlotte, NC (US)

Correspondence Address: ADAMS INTELLECTUAL PROPERTY LAW, P.A., Suite 2350 Charlotte Plaza, 201 South College Street, CHARLOTTE, NC, 28244, US

(73) Assignee: IMAGING SOURCE, LLC, Charlotte, NC (US)

(21) Appl. No.: 12/200,205

(22) Filed: Aug. 28, 2008

Related U.S. Application Data
(60) Provisional application No. 60/980,271, filed on Oct. 16, 2007.

(51) Int. Cl. G01J 5/00; H01L 27/14

(52) U.S. Cl. 250/338.3; 250/338.4

(57) ABSTRACT

An apparatus for converting ambient infrared radiation into electricity including an array of patch resonators each including a metal material having a predetermined shape tuned to resonate within a predetermined frequency range, a micro-strip line network for interconnecting the resonators and guiding energy, a dielectric substrate, and a metal ground plane. A micro-structured array of interconnected patch resonators operable for converting ambient heat to electricity, cooling, controlling temperature and wireless communication.

### CROSS-REFERENCE TO RELATED APPLICATION

This application claims priority to Provisional Patent Application No. 60/980,271 filed Oct. 16, 2007, the contents of which are incorporated by reference herein.

### TECHNICAL FIELD AND BACKGROUND OF THE INVENTION

1. Field of the Invention

The present invention relates generally to the field of power generation, and more specifically, to energy converting apparatus and methods for converting ambient heat in the form of infrared radiation into electricity.

2. Description of the Related Art

Due to the steadily increasing costs of fossil fuels and environmental concerns over using depletable fuel types, there exists a need for deriving energy from alternative, readily available and renewable energy sources. Examples of energy sources that are virtually unlimited in availability include solar energy, thermal energy stored in the earth, and energy from the ambient atmosphere in the form of infrared radiation. While there has been ongoing development in extracting energy in useful amounts from the sun and geothermal sources, there has been little work done in extracting energy from the ambient atmosphere in the form of ambient heat.

In this regard, it would be desirable to provide a device that functions to harvest unlimited ambient infrared radiation and convert the radiation directly into electricity, while at the same time cooling down the area surrounding the device. It would further be desirable to develop cooling and heating apparatus and methods that utilize ambient infrared radiation as an energy source. Desirable cooling and heating apparatus would be capable of precisely controlling temperature variances within electronic devices and microprocessors. Still further, it would be desirable to harvest infrared radiation for other purposes, such as for wireless communication.

### BRIEF SUMMARY OF THE INVENTION

In one aspect, the present invention provides energy converting apparatus and methods for simultaneously converting ambient infrared radiation into electricity and cooling down the surrounding area.

In another aspect, the present invention provides apparatus and methods for converting ambient infrared radiation into electricity for heating and cooling purposes. Energy transferred through a micro-structured array from a larger area having a specific temperature may be used to warm a smaller area above the temperature of the larger area when the smaller area is thermally insulated from the larger area. The apparatus is preferably impedance matched to maximize power transfer and minimize reflection. Electrical impedance may be matched using at least one of a transformer, resistor, microstrip line element, inductor and capacitor, among other components.

In another aspect, the present invention provides a micro-structured array for converting ambient heat into electricity for use in an integrated circuit to carry away depletion heat. The micro-structured array may be positioned inside or outside the integrated circuit for cooling purposes, and thus eliminates the need or reduces the size of a conventional heat sink including, but not limited to, a fan or metal heat sink. The micro-structured array may further function to control temperature variances within microprocessors and integrated circuits.

In yet another aspect, the present invention provides a micro-structured array for converting ambient heat into electricity adapted for use in refrigerators, cooling systems, and air conditioning systems without the need for providing external energy.

In yet another aspect, the present invention provides a micro-structured array for converting ambient heat into electricity adapted for use in insulated objects (e.g., thermos flask) to keep the medium inside at a specific temperature without the need for providing external power.

In yet another aspect, the present invention provides a micro-structured array for converting ambient heat into electricity adapted for use in data communication through altering polarization and impedance matching. Switches may be used to short-circuit the matching impedance or disconnecting the matching impedance from the micro-strip line network and a receiver may be used to interpret the different energy states on the micro-structured array.

In yet another aspect, the present invention may be used in combination with a peltier device to generate direct current, or may be combined with at least one rectifying device (e.g. a diode) to produce direct current.

To achieve the foregoing and other aspects and advantages, and in accordance with the purposes of the invention as embodied and broadly described herein, the present invention provides an energy converting apparatus including at least one micro-structured array for converting ambient heat energy in the form of infrared radiation into electricity. In one embodiment, an apparatus is provided that includes a predetermined number of resonating elements (antenna structures) that collectively form an array and are adjusted to a pre-selected frequency spectrum based on the size and shape of the metal of the resonating elements. The resonating elements include a metal, for example gold, silver or copper, positioned over a substrate, for example an organic polymer, which is positioned over a ground plane. The energy received by the resonating elements is guided away from the resonating elements along an attached micro-strip line network to a matching impedance. The attached micro-strip line network material may correspond to that of the resonating elements. An array may have a predetermined, specific shape based on the desired bandwidth(s) and/or application to be exploited. Several layers of micro-structured arrays may be stacked to form a converter apparatus and increase the efficiency and output of energy conversion. In one embodiment, one or more micro-structured arrays carry resonating elements at different resonance frequencies to increase the bandwidth of the apparatus. In a preferred embodiment, the desired frequency is infrared radiation having wavelengths between about 2 μm and about 30 μm.

In another embodiment, the present invention provides cooling and heating methods and apparatus utilizing ambient infrared radiation, including at least one array of micro-structured resonators connected through a micro-strip line network positioned on a substrate over a metal ground plane capable of absorbing infrared radiation, attaching a matching impedance to the output lead of the array, and providing thermal insulation between the array of micro-structured resonators and the matching impedance.

In yet another embodiment, the present invention provides a method and apparatus for converting ambient infrared radiation into electrical energy, including at least one array of micro-structured resonators connected through a micro-strip line network positioned on a substrate over a metal ground plane capable of absorbing infrared radiation, attaching a rectifier or rectifying material and a matching impedance between the output leads of the array of the micro-structured resonators and the ground plane for converting alternating current (AC) into direct current (DC). In yet another embodiment, the rectifier may be substituted for a Peltier device positioned between the array and the matching impedance to generate DC.

In yet another embodiment, the present invention provides a method and apparatus for wireless communication using ambient infrared radiation, including at least one array of micro-structured resonators positioned on a substrate over a metal ground plane capable of absorbing and reflecting infrared radiation, attaching a matching impedance to output leads of the array, attaching semiconductor switches in series and/or parallel to the matching impedance to switch between different energy states to transfer information and data. Termination impedance of the array may be infinitive, zero, in between or impedance matched. Adding further arrays having different orientations the methods may be used to realize various polarizations states of the micro-structured array.

### BRIEF DESCRIPTION OF THE DRAWINGS

These and other features, aspects and advantages of the present invention are better understood when the following detailed description of the invention is read with reference to the accompanying drawings, in which:

FIG. 1 is a schematic diagram of a single resonating element in accordance with an embodiment of the present invention;

FIG. 2 is a schematic diagram of a portion of a micro-structured array including a plurality of resonating elements interconnected through a micro-strip line network;

FIGS. 3-6 are resonating elements arranged in varying patterns according to embodiments of the present invention;

FIGS. 7-8 are thermal images of a micro-structured array with and without matching impedance, respectively; and

FIG. 9 is a thermal image of a micro-structured array cooled to a temperature out of its operating range.

### DETAILED DESCRIPTION OF THE INVENTION

The present invention will now be described more fully hereinafter with reference to the accompanying drawings in which exemplary embodiments of the invention are shown. However, the invention may be embodied in many different forms and should not be construed as limited to the representative embodiments set forth herein. The exemplary embodiments are provided so that this disclosure will be both thorough and complete, and will fully convey the scope of the invention and enable one of ordinary skill in the art to make, use and practice the invention. Like reference numbers refer to like elements throughout the various drawings.

The present invention provides energy converting apparatus including micro-structured arrays for converting ambient heat into electricity for cooling/heating purposes, power generation, and data transmission without requiring an input of external power. Micro-structured arrays of the present invention may include resonators, micro-strip line elements and networks, transformers, substrates, ground planes, resistors, semiconductors and switches, among other components. The micro-structured arrays provided herein may include any number of resonating elements arranged in various predetermined arrangements in one or more layers, and preferably includes a large number of resonating elements (patches, dipoles, cavities), for example more than about 100,000 resonating elements, that are tuned and resonate within a pre-selected frequency range. In a preferred embodiment, the resonating elements resonate in the infrared band between about 75 THz and about 10 THz. For energy conversion, the resonating elements preferably have a wide bandwidth. Due to the un-polarized nature of ambient heat radiation, the resonating elements gain and the micro-structured array gain (energy output) are increased when the resonating elements are designed without a preferred polarization direction.

The total radiated energy for a specific temperature can be calculated using Stefan-Boltzmann's Law. The wavelength λₘₐₓ associated with the measured temperature can be calculated using Wien's displacement law. The energy radiated in a specific range of wavelengths can be calculated using Planck's Law for black-body radiation. For example, a measured temperature of about 20° C. (68° F.) is equivalent to about 418 W/m² where λₘₐₓ=9.89 μm and about 80% of the total energy is distributed between λ₁=5 μm and λ₂=23 μm or expressed as frequencies in between 13 THz to 60 THz. These wavelengths lie in the infrared band, which is specified as having wavelengths between about 750 nm and about 1 mm, spanning three orders of magnitude.

At least one thermal insulator may be placed between micro-structured arrays and impedance matching elements to increase the efficiency of the converter apparatus. In practice, the large amount of resonating elements may require several separated micro-strip networks to increase efficiency. For data transmission devices in particular, the resonating elements reflect electromagnetic waves with a specified polarizing direction. The resonating frequency may be designed with respect to λₘₐₓ of the lowest expected temperature. Due to the large amount of resonating elements on one device, different polarization characteristics can be realized on the same device. The frequency range may be determined and tuned by the size and shape of the resonating elements. Several micro-structured arrays may be arranged to form clusters to increase the transmitting bandwidth or to encrypt the transmitted data. Data transmission is realized by altering the matching impedance of the micro-structured arrays or in switching between different polarization characteristics that are evaluated by a receiving device.

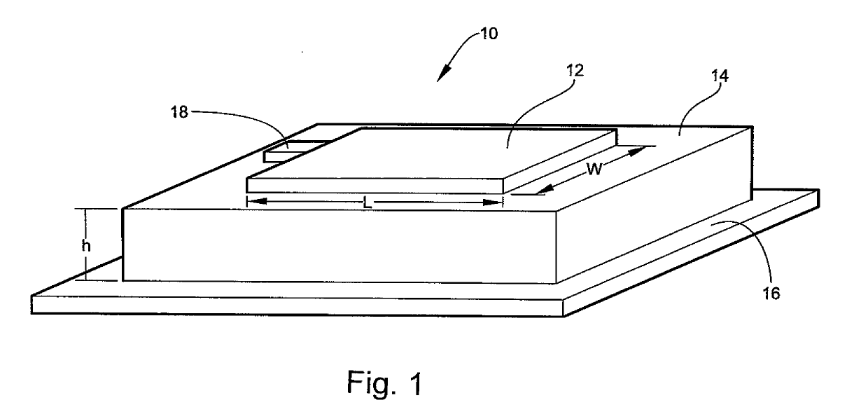

Referring now to the figures, FIG. 1 shows schematically an exemplary embodiment of a single resonating element of a micro-structured array. The resonating element 10 includes a generally rectangular-shaped λ/2 patch resonator 12 positioned on a dielectric substrate 14 with a low εᵣ over a ground plane 16. The substrate 14 may be made from any suitable material including, but not limited to, an organic polymer. The ground plane 16, patch resonators 12 and micro-strip line network 18 are preferably made from gold or other suitable material known to those skilled in the art. In an exemplary embodiment, the length Lₚ of a single patch resonator is about 4.25 microns and the width Wₚ is about 3.1 microns. Frequency tuning is accomplished by sizing and shaping the patch resonators 12, which have about a 10% bandwidth. Thus, the patches are adjusted to different frequencies based on the dimensions of the metal of the patch resonator 12 (length and width), and shape of the patch, such as a complex shape. In alternative embodiments, the lengths may vary from about 1.5 microns to 15 microns and widths may vary from about 1.0 microns to 11 microns to exploit a bandwidth from about 3.5 μm to 30 μm.

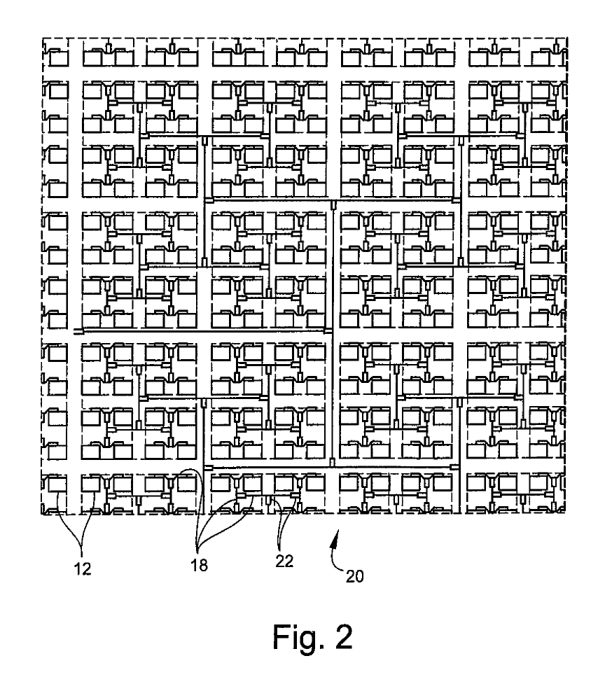

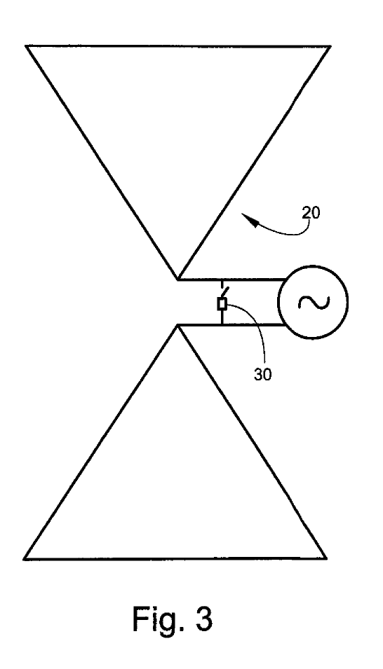

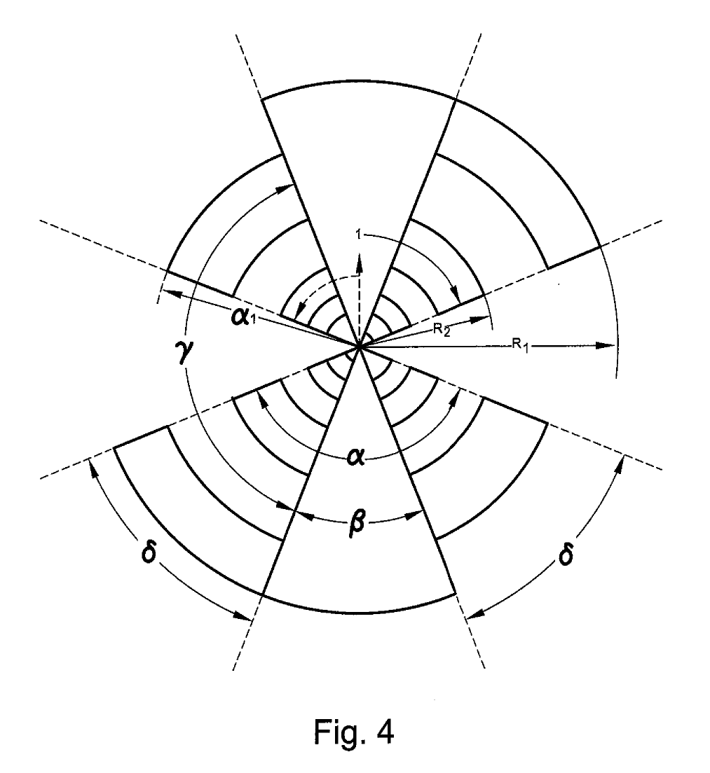

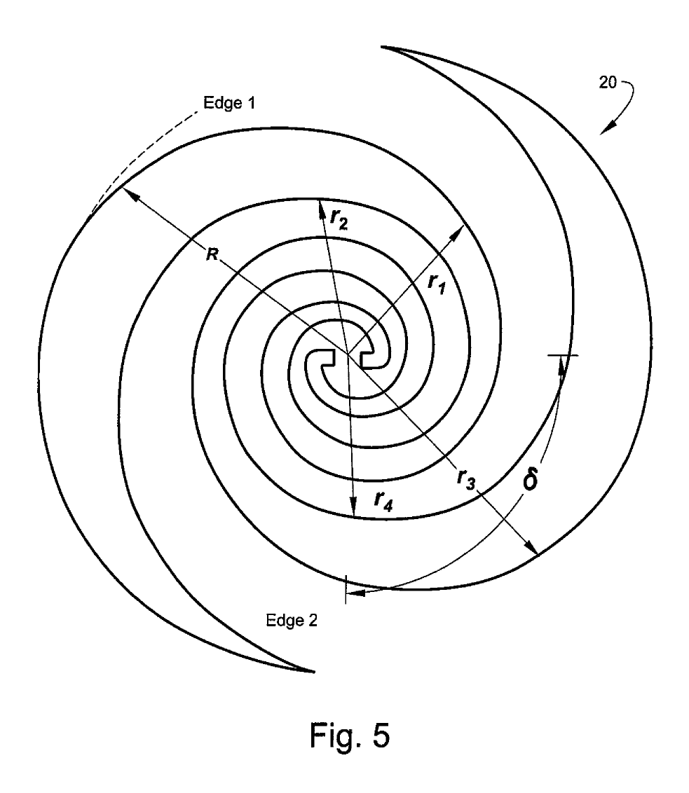

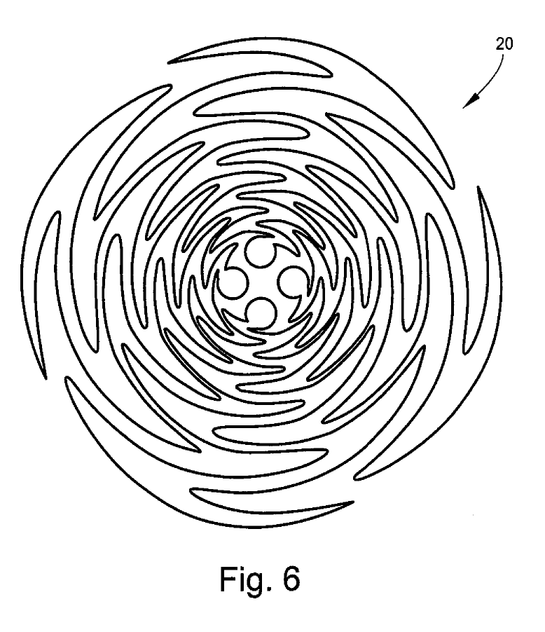

Referring to FIG. 2, an exemplary micro-structured array 20 includes a predetermined number of patch resonators 12 interconnected through a micro-strip line network 18 operable for guiding electromagnetic waves in predetermined directions through the dielectric material and surrounding air. A plurality of transformers 22 may be positioned along the paths of the micro-strip line network 18 for impedance matching of connecting micro-strip lines. In one example, an about 4 mm×4 mm array may include about 250,000 patch resonators 12. In alternative embodiments, the array may include from about a few thousand to about several trillion patch resonators arranged in at least one layer. In the embodiment shown, less than about 30% of the surface of the array 20 comprises patch resonators 12. FIGS. 3-6 illustrate micro-structured arrays of varying patterns for optimizing predetermined bandwidths and applications, and the arrangements are not intended to limit the antennae structure and shape of the present invention.

Still referring to FIG. 2, a load 30 is coupled with the array 20 through an output lead 32. The load 30 and array 20 are preferably impedance matched to maximize power transfer and minimize reflection. The array 20 and load 30 may be impedance matched using any combination of transformers, resistors, inductors and capacitors, and microstrip line elements, shown generally at 34, positioned between the array and load. The impedance matching components may be optimized for different applications.

The rectangular-shaped resonating element shown in FIG. 1 is designed to work close to its resonance frequency to achieve a real output impedance. In one experiment, the resonance frequency of the resonating element was chosen with respect to 20° C. (68° F.), which is related to λₘₐₓ of about 9.9 μm and a resonance frequency of about 30 THz. The substrate thickness (h in FIG. 1) was in the range of h>=0.1 λ The bandwidth of the patch behaved inverse reciprocal to εᵣ. In other words, a low εᵣ is important for a high bandwidth. The length L_{P} of the basic resonating element was slightly shorter than λ/2 in the dielectric and depended on h, εᵣ, and W_{P}. W_{P} was used to adjust the output impedance of the resonating element. For energy harvesting purposes, a rough estimation provides the following result: assuming a temperature slightly higher than 20° C. and a resonating array at 30 THz and a micro-structured array of 512×512 resonating elements covering an area of about 3.4 mm² produced an output power of about 0.5 mW at the matching impedance.

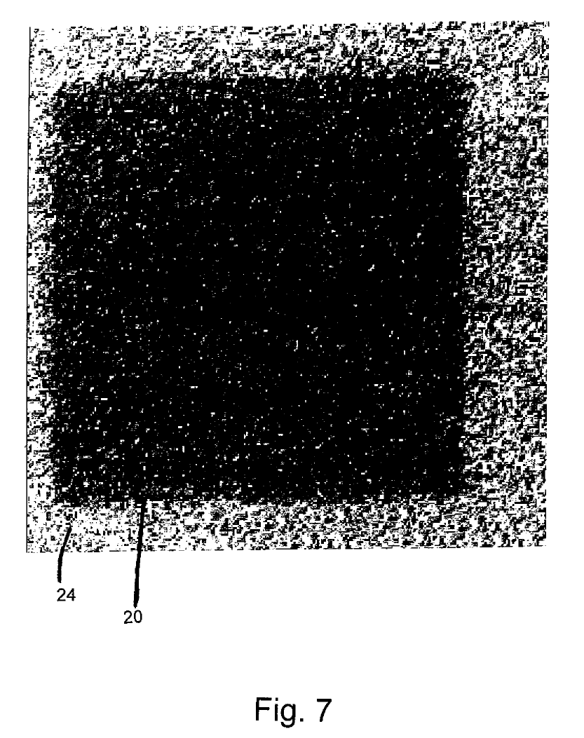

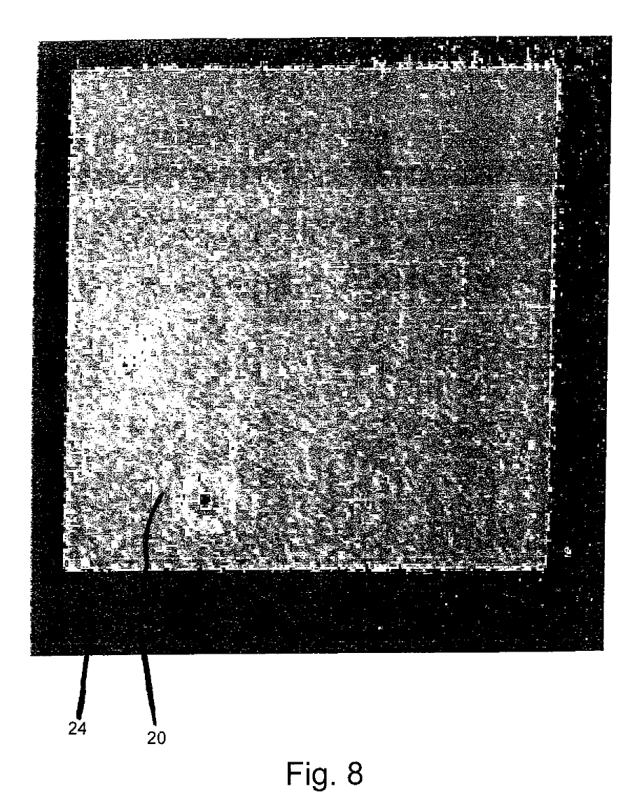

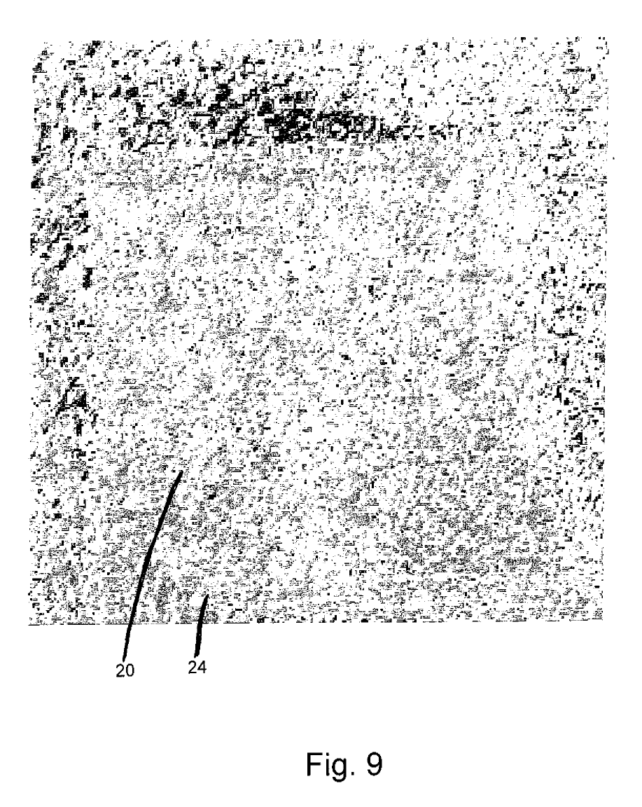

Referring to FIGS. 7-8, thermal images taken of a micro-structured array against its surrounding environment are shown. Referring specifically to FIG. 7, the micro-structured array 20 is terminated by matching impedance, and the darker color of the array compared to the surrounding background 24 indicates that the array is cooler than the surrounding area. Referring specifically to FIG. 8, the same micro-structured array 20 of FIG. 7 is not terminated by matching impedance, and the lighter color of the array 20 compared to the surrounding background 24 indicates that the array is hotter than the surrounding area. In the latter case, the micro-structured array works as a thermal mirror. Referring specifically to FIG. 9, a thermal image of a micro-structured array is shown cooled to a temperature about 22° F., a temperature out of its operating range and thus the temperature of the array is in thermal equilibrium with its environment, indicated by a lack of contrast in shade between the array 20 and the surrounding background 24.

A micro-structured array can be used to cool an area. In combination with a Peltier device, this method can be used to convert ambient heat into a direct current. The micro-structured array can also be used for data communication by altering matching impedance and/or polarization using a switch or adjustable impedance to realize different energy states and interpreting the energy states with a receiver.

With regard to cooling, the micro-structured array of the present invention may be used to cool an insulated space (refrigerator) or an integrated circuit or control temperature variances within integrated circuits that generate heat. The array 20 is adapted to and positioned so as to be positioned inside the insulated space or thermally coupled to the integrated circuit or processor. The array 20 coupled with a Peltier device may be configured to convert the heat from the integrated circuit to electrical energy.

The foregoing is a description of various embodiments of the invention that are given here by way of example only. Although micro-structured arrays for converting ambient heat to electricity, while at the same time cooling the surrounding area have been described with reference to specific embodiments thereof, other embodiments may perform similar functions and/or achieve similar results. Any and all such equivalent embodiments and examples are within the spirit and scope of the present invention and are intended to be covered by the appended claims.

1. An apparatus for converting ambient infrared radiation into electricity, comprising:
a plurality of patch resonators each including a metal material having a predetermined size and shape tuned to resonate within a predetermined frequency range, wherein the plurality of patch resonators collectively form an array;
a micro-strip line network interconnecting the plurality of patch resonators and operable for guiding energy from the plurality of patch resonators to a matching impedance;
a dielectric substrate supporting the plurality of patch resonators and the micro-strip line network; and
a metal ground plane.

2. The apparatus according to claim 1, wherein each of the plurality of patch resonators has a length from about 1.5 microns to about 15 microns and a width from about 1.0 microns to about 11 microns to exploit a bandwidth from about 3.5 μm to about 30 μm.

3. The apparatus according to claim 1, further comprising at least one transformer positioned along the micro-strip line network for impedance transformation of connecting micro-strip lines.

4. The apparatus according to claim 1, wherein the array comprises from about a few thousand to about several trillion patch resonators arranged in at least one layer.

5. The apparatus according to claim 1, further comprising an output lead coupled with the micro-strip line network for coupling a load to the array, wherein the micro-strip line network and the load have matching impedances.

6. An apparatus for converting ambient heat to electricity for cooling and controlling temperature, comprising:
a micro-structured array of patch resonators for absorbing infrared radiation interconnected through a micro-strip line network, the patch resonators and micro-strip line network positioned on a dielectric substrate over a metal ground plane;
a load impedance matched to the micro-strip line network and coupled through an output lead of the micro-strip line network; and
thermal insulation positioned between the micro-structured array and the load.

7. The apparatus according to claim 6, wherein the device includes a Peltier device.

8. The apparatus according to claim 6, wherein the load includes a rectifier coupled to the output lead for rectifying alternating current into direct current.

9. A method for converting ambient infrared radiation to electricity while cooling a surrounding area, comprising:
providing at least one micro-structured array of patch resonators for absorbing infrared radiation interconnected through a micro-strip network positioned on a substrate over a metal ground plane;
coupling a load having matching impedance to that of the microstrip network; and
thermally insulating the at least one micro-structured array from the load.

10. A method for wireless communication utilizing ambient infrared radiation, comprising:
providing at least one array of micro-structured resonators positioned on a substrate over a metal ground plane capable of absorbing and reflecting infrared radiation;
coupling a matching impedance to an output lead of the at least one array of micro-structured resonators and the ground plane; and
coupling at least one semiconductor switch in series and/or parallel to the matching impedance to switch between different energy stages of the at least one array of micro-structured resonators to transfer information and data.

11. The method according to claim 10, wherein a termination impedance of the at least one array of micro-structured resonators is one of: infinitive zero, impedance matched, or between zero and infinitive.
